(19) United States
(12) Patent Application Publication
(10) Pub. No.: US 2019/0109103 A1
(43) Pub. Date: Apr. 11, 2019

(54) Method of Forming a Semiconductor Package and Semiconductor Package

(71) Applicant: Infineon Technologies AG, Neubiberg (DE)

(72) Inventors: Chau Fatt Chiang, Melaka (MY); Khar Foong Chung, Menglembu (MY); Johanna Ocklenburg, Munich (DE)

(21) Appl. No.: 16/155,060

(22) Filed: Oct. 9, 2018

(30) Foreign Application Priority Data
Oct. 9, 2017 (DE) 102017123360.1

(51) Int. Cl. H01L 23/66; H01L 23/538; H01Q 1/22; H01L 21/56; G01S 13/93

(52) U.S. Cl. CPC H01L 23/66; H01L 23/5389; H01L 2223/6677; H01L 21/565; G01S 13/931; H01Q 1/2283

(57) ABSTRACT

Various embodiments provide a method of forming a semiconductor package. The method includes arranging a semiconductor die and a first substrate, wherein the first substrate includes a first side, wherein the first side includes a first electrical contact. The method may include forming a mold structure to encapsulate the semiconductor die and the first substrate. The method may further include providing a three-dimensional antenna in the mold structure to electrically couple to the first electrical contact. Various embodiments also provide a semiconductor package including a semiconductor die and a first substrate encapsulated by a mold structure. A three-dimensional antenna is provided in the mold and electrically coupled to the first substrate.

### TECHNICAL FIELD

Various embodiments relate generally to a method of forming a semiconductor package and to a semiconductor package.

### BACKGROUND

Recently, vehicle assistant systems and even systems for fully autonomous vehicles have become more and more attractive. These systems require the knowledge of the surroundings of the vehicle, for which detection systems are used.

In some systems, Light Detection And Ranging (LIDAR) is used, wherein the surroundings of the vehicle is scanned and the information is processed to try to determine the relative position of the vehicle, e.g. to the lane and to the other objects within its surroundings. LIDAR detectors are specially used for long range measurements, because the used laser and photodetector can be used for relatively long distances while the signal still being detectable. However, LIDAR systems are very costly, since they require expensive optics and moving parts for the scanning.

In other systems, radar is used, requiring a complex arrangement, for example, of electronic circuits, antenna, antenna protection, and mechanical fixture. These systems are relatively complex and costly.

For these reasons, radar and LIDAR systems are also very bulky and occupy considerable space.

### SUMMARY

In various embodiments, a method of forming a semiconductor package is provided. The method may include providing a semiconductor die and a first substrate. The semiconductor die includes a die contact. The first substrate includes a first side, and the first side includes a first electrical contact . The method may also include forming a mold structure to encapsulate the semiconductor die and the first substrate; and providing a three-dimensional antenna in the mold structure to electrically contact the first electrical contact.

In various embodiments, a semiconductor package is provided. The semiconductor package may include a first substrate including a first side and second side, wherein the first side includes a first electrical contact. The semiconductor package may also include a semiconductor die, which comprises a die contact. The semiconductor package may also include a mold structure, wherein the semiconductor die and the first substrate are encapsulated by the mold structure. The semiconductor package may also include a three-dimensional antenna provided in the mold structure, wherein the three-dimensional antenna is electrically coupled to the first electrical contact.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the embodiments. In the following description, various embodiments are described with reference to the following drawings, in which:

FIG. 1 shows a schematic view of three stages of the method of forming the semiconductor package in accordance with the invention. In FIG. 1, by way of example, the three-dimensional antenna is formed in the opening of the mold structure;

FIG. 2 shows a schematic view of a modified method of the method illustrated in FIG. 1, in accordance with the invention. In FIG. 2, by way of example, the three-dimensional antenna is provided as a pre-formed three-dimensional antenna and placed onto the first electrical contact, before the mold structure is formed;

FIG. 3 shows a schematic view of the method according to the invention, wherein a plurality of semiconductor packages is formed;

FIG. 4 shows a schematic view of the method according to the invention, in one alternative FIG. 3, wherein a plurality of semiconductor packages is formed;

FIG. 5 shows a schematic perspective view of a semiconductor package in accordance with various embodiments;

FIG. 6 shows a schematic perspective view of a semiconductor package in accordance with various embodiments, wherein the three-dimensional antenna is a metal trace.

FIG. 7 shows a schematic perspective view of a semiconductor package in accordance with various embodiments, wherein the inner part of the three-dimensional antenna is filled with a dielectric material;

FIG. 8 shows a schematic perspective view of a semiconductor package in accordance with various embodiments, wherein a dielectric lens is attached to the three-dimensional antenna;

FIG. 9 shows a schematic perspective view of a semiconductor package in accordance with various embodiments, wherein a dielectric lens includes metal traces;

### DETAILED DESCRIPTION

The following detailed description refers to the accompanying drawings that show, by way of illustration, specific details and embodiments in which the invention may be practiced.

The word “exemplary” is used herein to mean “serving as an example, instance, or illustration”. Any embodiment or design described herein as “exemplary” is not necessarily to be construed as preferred or advantageous over other embodiments or designs.

The word “over” used with regards to a deposited material formed “over” a side or surface, may be used herein to mean that the deposited material may be formed “directly on”, e.g. in direct contact with, the implied side or surface. The word “over” used with regards to a deposited material formed “over” a side or surface, may be used herein to mean that the deposited material may be formed “indirectly on” the implied side or surface with one or more additional layers being arranged between the implied side or surface and the deposited material.

The term “upper side”, or “upper surface”, of the mold structure means the side that is further away from the first substrate.

The term “in” used to describe the spacial relation between the three-dimensional antenna (or additional three-dimensional antenna) and the the mold structure (e.g. in “providing a three-dimensional antenna in the mold structure”) means that the three-dimensional antenna is at least partially surrounded by the mold structure. It may also mean that the three-dimensional antenna provide so as to extend through the mold structure. The three-dimensional antenna's side proximal to the upper side of the mold layer (distal from the common substrate or the first substrate) may be receded or flush with the surface of the mold structure. Alternatively, the three-dimensional antenna's side proximal to the upper side of the mold layer (distal from the respective substrate) may protrude from the surface of the mold structure. The “respective substrate” means the substrate over which the three-dimensional antenna is provided, for the three-dimensional antenna it may be the first susbtrate or the common susbtrate, for the additional three-dimensional antenna it may be the common susbtrate, the second substrate or an additional substrate.

Various aspects of the disclosure are provided for a three-dimensional antenna. In various embodiments, an additional three-dimensional antenna may be included. The additional three-dimensional antenna can be formed and/or provided in the same way as the three-dimensional antenna. For example, both, the three-dimensional antenna and the additional three-dimensional antenna may be different from each other or may be identical. Is various aspects of the disclosure, the plural antennae is used. In various aspects, the disclosure is explained for the three-dimensional antenna but referring to the plural in parenthesis such as “antenna(e)”, it means that the disclosure applies to at least one of the three-dimensional antenna or the additional three-dimensional antenna. The additional three-dimensional antenna may be provided on the on the common substrate, on the second substrate, or on an additional substrate, which additional substrate may have the same characteristics as the first substrate.

The figures show a three-dimensional antenna and an additional three-dimensional antenna by way of example, however the semiconductor package may not include the additional three-dimensional antenna, or the semiconductor package may include the additional three-dimensional antenna. The semiconductor package may include further antennae.

Various aspects of the disclosure are provided for methods, and various aspects of the disclosure are provided for packages. It will be understood that basic properties of the packages also hold for the methods and vice versa. Therefore, for sake of brevity, duplicate description of such properties may have been omitted.

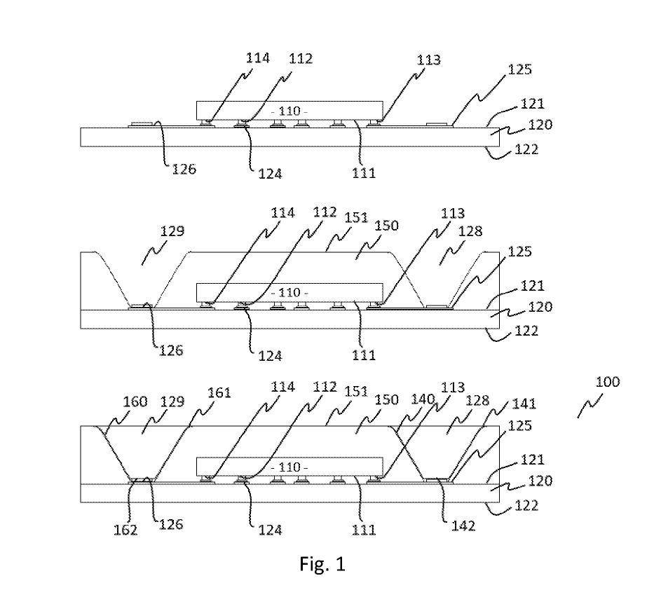

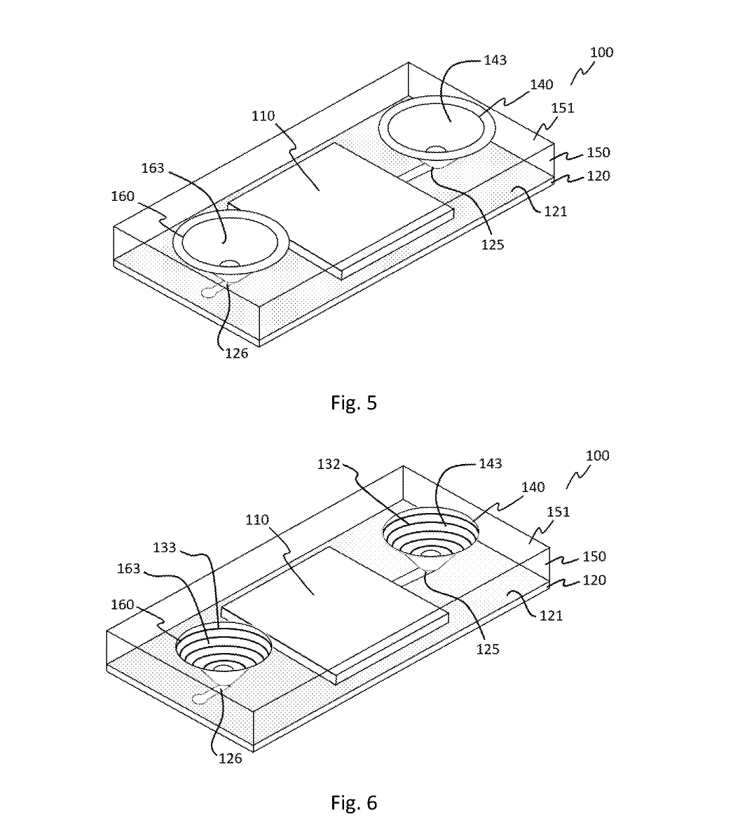

By way of example, and with reference to the figures, the method according to the invention includes providing a first substrate, a die such as e.g. a flip-chip, electrically coupled to the first substrate and one or more three-dimensional antennae. The antennae may send and/or receive signals such as radar signals. These components are, for example, held together and monolithically integrated by the mold structure. The invention describes a method, such as schematically shown in FIGS. 1 to 4, with various advantageous embodiments to produce the semiconductor package as schematically shown in FIGS. 5 to 9. The external electrical connections to the semiconductor packaging is not shown in the figures, but may include contacts in standard geometry and arrangements such that the can be applied in the electronic industry, e.g. as a chip.

The first substrate and the semiconductor die may be arranged side-by-side, thus allowing for electrical connections being formed at a same plane, for example, at the bottom side as shown by way of example in FIG. 1.

In various embodiments, the semiconductor die may include a die contact. In some embodiments, the semiconductor die may be provided on a second substrate. The second substrate includes a first side and a second side, wherein the first side includes a second electrical contact. The first electrical contact may be electrically coupled to the second die contact via e.g. a wire to be encapsulated. In the case of a common substrate, the first electrical contact may be electrically coupled to the second die contact via e.g. a conductive trace. Alternatively, the first electrical contact may be electrically coupleable to the second die contact via e.g. external connections e.g. to be provided on the application of the semiconductor package. In some embodiments, for example for external connections, it may be provided that the semiconductor die is provided such that the die contact is located on the side distal to the upper side of the mold layer (thus up-side-down as shown in the figures).

In various embodiments, the method includes forming a mold structure to encapsulate the semiconductor die, the first substrate and the second substrate.

In various embodiments the first substrate and the second substrate may be part of a common substrate. A common substrate means a single, continuous structure satisfying the requirements of the first substrate and the second substrate. The common substrate is referred herein as “common substrate”. The following detailed description shows, by way of illustration, a common substrate, however the invention is not limited thereto.

In some embodiments, when referring to a common substrate, an electrical coupling may be via conductive traces.

In some embodiments, when referring to different substrates, for example the first substrate and the second substrate, an electrical coupling may be via a wire, for example a wire bonded to a point of one substrate to a point of the other substrate, the wire may be encapsulated in the mold structure. The electrical coupling may also be external, in such case the two points to be coupled may be referred to as electrically coupleable, since the external connection may be provided at a later stage, for example on the application level. “External” refers to external to the semiconductor package.

In some embodiments, the method may include: arranging the semiconductor die and the second substrate above one another, wherein the second substrate includes a first side, wherein the first side includes the first electrical contact and the second electrical contact, and wherein the semiconductor die includes the die contact, wherein the first electrical contact pad is electrically coupled to the die contact; and forming a mold structure to encapsulate the semiconductor die and the second substrate, thus encapsulating the semiconductor die, the first substrate and the second substrate.

In some embodiments, the method may include: arranging the semiconductor die and the common substrate above one another, wherein the common substrate includes a first side, wherein the first side includes the first electrical contact and the second electrical contact, and wherein the semiconductor die includes the die contact, wherein the first electrical contact pad is electrically coupled to the die contact; and forming a mold structure to encapsulate the semiconductor die and the common substrate, thus encapsulating the semiconductor die and the common substrate.

FIG. 1 shows three stages of the method of forming the semiconductor package 100, in accordance with various embodiments. FIG. 1 shows, on top, a schematic view of a semiconductor die 110 arranged on a common substrate 120. The common substrate 120 includes a first side 121 and a second side 122. The first side 121 and the second side 122 are opposite sides of the common substrate 120. The first side 121 includes a first electrical contact 125 and a second electrical contact 124. The first side 121 may include more contacts. The semiconductor die 110 includes a die contact 112, and the die contact 112 is electrically coupled to the second electrical contact 124. The first electrical contact 125 may be electrically coupled to a second die contact 113, via e.g. a conductive trace. As shown in FIG. 1, in the middle, a mold structure 150 is formed over the first substrate 120, to encapsulate the semiconductor die 110.

In a variation of the figures, and in some embodiments, a first and a second substrate could be provided instead of the common substrate 120, in such case the semiconductor die 110 would be arranged on the second substrate. The first side and the second side of each of the first substrate and the second substrate correspond to the respective first and second sides of the common substrate in the semiconductor package 100.

In another variation of the figures, and in some embodiments, the semiconductor die 110 may be arranged without being arranged over a substrate in the case in which no second substrate is provided. The first side and the second side of the first substrate corresponds to the respective first and second sides of the common substrate in the semiconductor package 100. The first electrical contact 125 may be electrically coupled to the second die contact 113 via e.g. a wire to be encapsulated. Alternatively, the first electrical contact 125 may be electrically coupleable to the second die contact 113 via e.g. external connections e.g. to be provided on the application of the semiconductor package.

In various embodiments, the mold structure 150 includes an opening 128 exposing at least a portion of the first electrical contact 125. An example schematic is shown in FIG. 1, in the middle.

In various embodiments, the three-dimensional antenna 140 is formed in the opening 128. An example schematic is shown in FIG. 1, at the bottom of the figure.

In some embodiments, and as illustrated in FIG. 1, the common substrate may include an additional contact 126. The additional contact may be included in the first substrate, in the second substrate, or in the additional substrate. The additional contact 126 may be electrically coupled or coupleable to an additional die contact 114.

In various embodiments, the mold structure 150 may include an additional opening 129 exposing at least a portion of the additional electrical contact 126. An example schematic is shown in FIG. 1, in the middle.

In various embodiments, an additional three-dimensional antenna 160 is formed in the additional opening 129. An example schematic is shown in FIG. 1, at the bottom of the figure.

In various embodiments, the providing the three-dimensional antenna is carried out after the forming the mold structure.

In various embodiments, the providing the three-dimensional antenna is carried out after the forming the mold structure and the three-dimensional antenna is formed in the opening.

In various embodiments, the opening 128 is at least partially formed, e.g. completely formed, during the process of forming the mold structure 150, e.g. during a molding process. For example, the material forming the mold structure is deposited in regions other than the opening 128, thus forming the mold structure 150 with the desired opening 128. This may have the effect of saving material and processes. The additional opening 129 may be formed in the same manner.

Alternatively, the opening 128 is at least partially formed, e.g. completely formed, after forming the mold structure without the opening 128. The mold structure without the opening is formed first. For example, by depositing the material forming the mold structure. In another process, the opening 128 is formed into the mold structure. For example, by removing the material of the mold structure in the region of the opening 128. This may have the effect of process flexibility, since the availability and form of the opening(s) can be defined afterwards, on the encapsulated semi-finished package. The additional opening 129 may be formed in the same manner.

In various embodiments, the opening 128 has a shape capable of receiving the three-dimensional antenna 140.

The additional opening 129 may have a shape capable of receiving the additional three-dimensional antenna 160.

The three-dimensional antenna 140 may be provided as a pre-formed three-dimensional antenna and placed onto the first electrical contact 125, for example as a metal structure. The pre-formed three-dimensional antenna (or additional pre-formed three-dimensional antenna) may be made for example by metal stamping, or metal etching. The pre-formed three-dimensional antenna (or additional pre-formed three-dimensional antenna) may be provided by a pick and place method.

In various embodiments, the additional three-dimensional antenna 160 is provided as a pre-formed three-dimensional antenna and placed onto the additional electrical contact 126.

Instead of placing a pre-formed three-dimensional antenna, the three-dimensional antenna 140 may be formed in the opening 128 of the mold structure 150. By way of example, the forming is done by depositing a metal in the opening, for example by electroplating. In some embodiments, the inner surface of the opening 128 is covered by a metal. The additional three-dimensional antenna 160 can be formed in the same manner in the additional opening 129. In various embodiments, the opening(s) (128,129) may be filled with a metal, which is afterwards partially removed to form the inner shape of the antenna(e) (140, 160). The three-dimensional antenna 140 (or additional three-dimensional antenna 160) can be electrically coupled to the first electrical contact 125 (additional contact 126), e.g., by way of forming the metal on the first electrical contact 125 (additional contact 126). Alternatively, in various embodiments, the inner surface of the opening 128 is covered by a metal layer. The additional three-dimensional antenna 160 can be formed in the same manner in the additional opening 129. That may have the effect that the shape of the opening can define the shape of the antenna(e) thus providing great flexibility in choice for the shape of the antenna(e) shape. The antenna 140 (or additional three-dimensional antenna 160) can be electrically coupled to the first electrical contact 125 (additional contact 126), e.g., by way of forming the metal on the first electrical contact 125 (additional contact 126).

By forming the antenna within the package body, the three-dimensional antenna(e) may include any type of shape, size and material.

In various embodiments, the antenna(e) may be formed by chemical vapor deposition (CVD), physical vapor deposition (PVD), electrochemical deposition, or the like.

In various embodiments, the antenna(e) may be patterned into a desired structure, e.g. by chemically etching.

The figures illustrate the first electrical contact and the second electrical contact as being on the first substrate's surface. These contacts may also be flush to the first substrate and/or at least partially embedded into the first substrate.

The first electrical contact and the second electrical contacts may be contact pads.

The figures illustrate the die electrical contacts as being on the surface of the semiconductor die. These contacts may also be integrated into (instead of “on” to) the surface of the semiconductor die. These contacts may further be at least partially embedded into the surface of the semiconductor die, or even flush with the surface. Flush means essentially not protruding out of the plane of the surface.

The figures illustrate the first, second, and additional electrical contacts as being on the substrate's (common, first, or second as applicable) surface. These contacts may also be integrated into (instead of “on” to) the substrate's surface. These contacts may further be at least partially embedded into the substrate's surface, or even flush with the surface. Flush means essentially not protruding out of the plane of the surface.

The substrate's (common, first, or second as applicable) contacts may be contact pads.

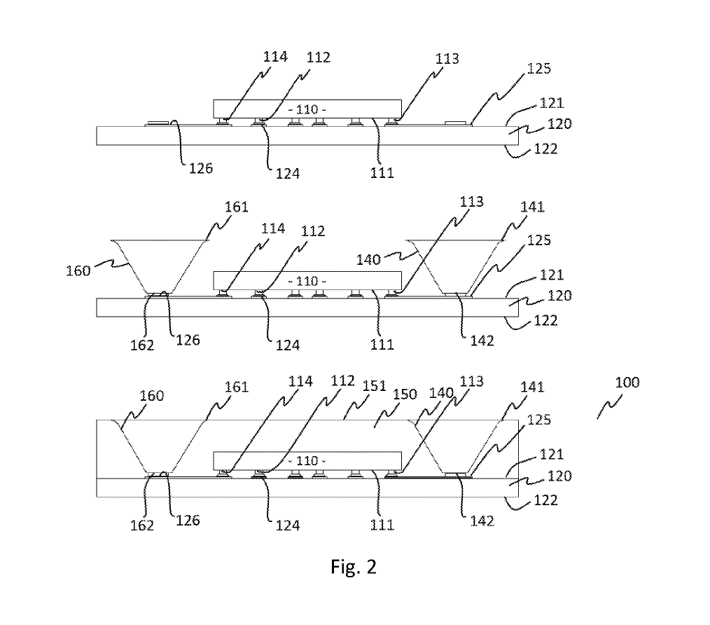

FIG. 2 shows three stages of the method of forming the semiconductor package 100, in accordance with various embodiments. FIG. 2 shows a modified method of the method illustrated in FIG. 1. FIG. 2 shows, on top, a schematic view of a semiconductor die 110 arranged on a common substrate 120. The common substrate 120 includes a first side 121 and a second side 122. The first side 121 and the second side 122 are opposite sides of the common substrate 120. The first side 121 includes a first electrical contact 125 and a second electrical contact 124. The first side 121 may include more contacts. The semiconductor die 110 includes a die contact 112, and the die contact 112 is electrically coupled to the second electrical contact 124. The first electrical contact 125 may be electrically coupled to a second die contact 113.

In various embodiments, and as illustrated in FIG. 2 by way of example, the three-dimensional antenna 140 is provided as a pre-formed three-dimensional antenna and placed onto the first electrical contact 125, before the mold structure 150 is formed. In the same manner, the additional three-dimensional antenna 160 may be provided as a pre-formed three-dimensional antenna and may be placed onto the additional electrical contact 126. This may have the effect that the pre-formed three-dimensional antenna(e) can be produced elsewhere, stored, and provided as needed for the production, thus providing production flexibility and time reduction.

In various embodiments, after the antenna(e) is(are) placed onto the respective electrical contact of the common substrate 120, the mold structure 150 is formed encapsulating the semiconductor die 110 and holding the antenna(e) in place. This may have the effect that a robust mechanical integration of the antenna(e) within the semiconductor package 100 can be provided by forming the mold structure 150.

FIGS. 1 and 2 illustrate each at the bottom, by way of example, the formed semiconductor package 100, wherein the package includes the common substrate 120 including the first side 121 and the second side 122, wherein the first side 121 and the second side 122 are opposite sides of the common substrate, and wherein the first side 121 includes a first electrical contact 125 and a second electrical contact 124. The package 100 includes, a semiconductor die 110 including a die contact 112, wherein the second electrical contact 124 is electrically coupled to the die contact 112. The semiconductor package includes a mold structure 150, wherein the semiconductor die 110 is encapsulated by the mold structure 150. The three-dimensional antenna 140 is electrically coupled to the first electrical contact 125. If available, the additional three-dimensional antenna 160 may be electrically coupled to the additional electrical contact 126.

In various embodiments, the semiconductor die includes at least part of a circuit to drive the antenna(e), for example the semiconductor die includes a driver.

In various embodiments, the semiconductor die includes at least part of a sender circuit, e.g. for radar.

In various embodiments, the semiconductor die includes at least part of a receiver circuit, e.g. for radar.

In various embodiments, the semiconductor die 110 is flip chip coupled to the first substrate 120.

In various embodiments, the three-dimensional antenna(e) may be fully within the package, thus without having portions protruding out of the mold structure. This may facilitate automatic handling of the semiconductor package, e.g. by pick and place machines.

In various embodiments, and as shown by way of example, in each of FIGS. 1 and 2, at the bottom, the three-dimensional antenna 140 includes a side 141 which is proximal to the upper side 151 of the mold structure 150. It may be provided that the antenna side 141 is flush with the upper side 151 of the mold structure 150. In analogous way, when an additional three-dimensional antenna 160 is present, the additional three-dimensional antenna 160 includes a side 161 which is proximal to the upper side 151 of the mold structure 150. It may be provided that the antenna side 161 is flush with the upper side 151 of the mold structure 150.

In various embodiments, the first substrate includes first substrate contacts on the second side 122 of the first substrate. When the semiconductor package 100 is formed, these contacts on the second side 122 of the first substrate can provide for electrical coupling between the exterior of the semiconductor package 100 and the semiconductor die 110, for example to the die contact 112 via the second electrical contact 124.

In various embodiments, a leadless semiconductor package may be provided. This may have the effect of providing a more compact form.

In various embodiments, the common substrate is a pre-formed mold structure. The term “pre-formed mold structure” refers herein to the common substrate, and is distinguished from the “mold structure” (without the “pre-formed”).

In various embodiments, the common substrate is formed by molding a pre-formed mold structure.

In various embodiments, the common substrate is a pre-formed mold structure including a leadframe. The term leadframe may refer to a leadframe for a package including electrical connecting pins. Alternatively, the term leadframe may refer to a “leadless” leadframe of a common substrate which, after the pre-formed mold structure is formed, is leadless. Leadless in the semiconductor field means free of length wires or pins for electrical connections, but including contacts, e.g. contact pads, instead.

In various embodiments, forming the mold structure 150 is carried out in a tool cavity. The allows for shape flexibility for the semiconductor package 100, and for forming a semiconductor package 100 with any suitable shape.

In various embodiments, a means for electrical coupling the three-dimensional antenna 140 to the first electrical contact 125 is provided. The means is illustrated, by way of example in FIGS. 1 and 2, as the element between the first electrical contact 125 and the side 142 of the three-dimensional antenna 140, which is proximal to the first substrate 120. The means can be, for example, solder paste. In the same manner, a means for electrical coupling the additional three-dimensional antenna 160 to the additional electrical contact 126 is provided. The means is illustrated, by way of example in FIGS. 1 and 2, as the element between the additional electrical contact 126 and the side 162 of the three-dimensional antenna 160, which is proximal to the first substrate 120. The means can be, for example, solder paste.

In various embodiments, the three-dimensional antenna 140 may be coupled to the first electrical contact 125 before forming the mold structure 150. For example by soldering the three-dimensional antenna 140 to the first electrical contact 125. In various embodiments, the additional three-dimensional antenna 160 may be coupled to the additional electrical contact 126 before forming the mold structure 150. For example, by soldering the additional three-dimensional antenna 160 to the additional electrical contact 126.

In various embodiments, the three-dimensional antenna 140 may be coupled to the first electrical contact 125 after forming the mold structure 150. For example by soldering the three-dimensional antenna 140 to the first electrical contact 125. In various embodiments, the additional three-dimensional antenna 160 may be coupled to the additional electrical contact 126 after forming the mold structure 150. For example by soldering the additional three-dimensional antenna 150 to the additional electrical contact 126.

In various embodiments, the method may include soldering the second electrical contact 124 with the die contact 112 on the one hand and the first electrical contact 125 with the three-dimensional antenna 140 in one common soldering process. The additional three-dimensional antenna 160 may be soldered to the additional electrical contact 126 also in the same said common soldering process. For example at the same time. As an example, by reflow soldering.

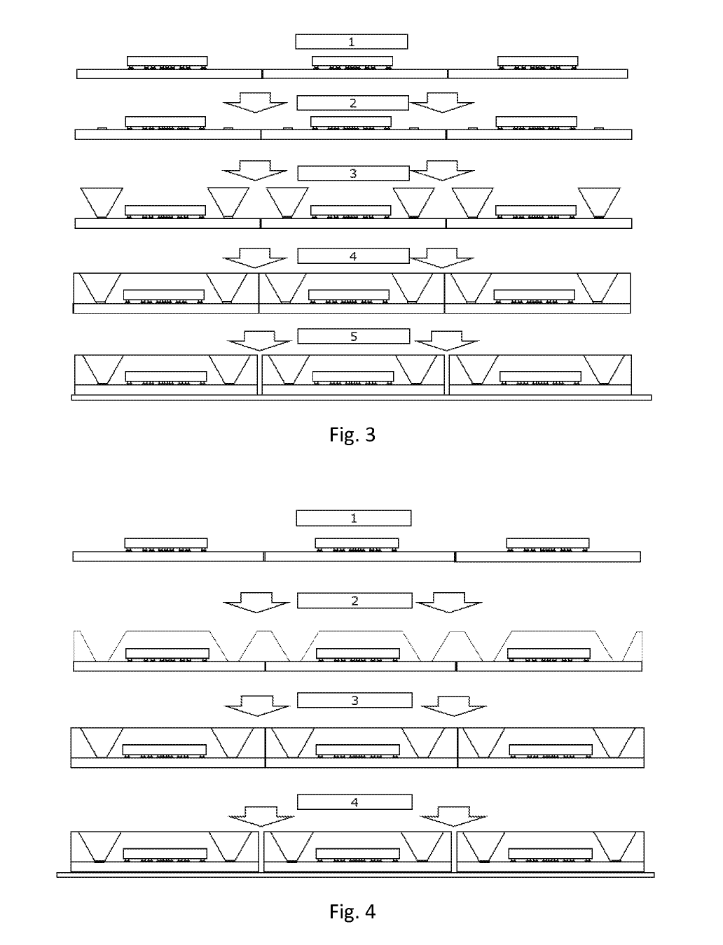

FIG. 3 shows a schematic view of the method in accordance with various embodiments. In process 1, three common substrates are shown before they are singulated. Three common substrates are used as an example, various embodiments may include 10 common substrates or more. For each common substrate, a semiconductor die may be attached in process 1. In process 2, solder paste may be dispensed of each corresponding first electrical contact. The solder paste may be dispensed at the same time on each additional electrical contact. In process 3, for each common substrate, the antenna(e) may be formed, and in process 4 the mold structure may be formed. Process 5 illustrates, by way of example, that the method may include singulation, thus forming three semiconductor packages according to various embodiments. The method may include lamination onto a carrier, such as a transport carrier.

FIG. 4 shows a schematic view of the method in accordance with various embodiments. In process 1, three common substrates are shown before they are singulated. Three common substrates are used as an example, various embodiments may include 10 common substrates or more. For each common substrate, a semiconductor die may be attached in process 1. In process 2 the mold structure may be formed. In process 3, for each common substrate, the antenna(e) may be formed or alternatively placed in the respective opening(s). Process 4 illustrates, by way of example, that the method may include singulation, thus forming three semiconductor packages according to various embodiments. The method may include lamination onto a carrier, such as a transport carrier.

In various embodiments the package may be used for radar sensing. The radar sensing application may be, for example, for vehicle assistant systems or autonomous drive vehicles.

The semiconductor package according to various embodiments is highly integrated. Due to the high integration it can be easily applied to diverse purposes. Interconnections between the semiconductor die and the antenna(e), as well as alignment of the antenna(e) in relation to the packaging can be dispensed with during application of the semiconductor packaging, since these components are all monolithically integrated. Due to the high integration, the semiconductor package can be handled by existing equipment for manufacturing electronic boards.

Due to the use of three-dimensional antenna(e), the method according to various embodiments may have the effect that semiconductor packages can be formed wherein the application range can be specified as required, by providing the respective three-dimensional antenna(e). For example, a semiconductor package can be formed for long range radar sensing, while another semiconductor package can be formed for short range radar sensing, with only relatively minor changes in the method of forming the semiconductor package (e.g., by providing an antenna with a different shape).

In various embodiments, different range sensing may be provided in the same semiconductor package, e.g. by providing a three-dimensional antenna with a different shape from the additional three-dimensional antenna.

In various embodiments, the three-dimensional antenna may be selected from at least one of: a conical horn antenna, a dielectric lens antenna, a dielectric lens antenna comprising metal traces on the lens, a helix antenna.

In various embodiments, the semiconductor die may be configured to emit the radar signal and receive the radar signal. In various embodiments the semiconductor die may be configured to process a receiving signal and provide processed data, for example, in digital form. Electrical coupling to the outside of the package may be provided by the contacts on the semiconductor die. Alternatively or in addition, electrical coupling to the outside of the package may be provided via the first substrate contacts formed on the second side of the first substrate and electrically coupled to the semiconductor die, for example to the die contact via the vires, formed e.g. via wire bonding. In yet another alternative, electrical coupling to the outside of the package may be provided via the common substrate contacts formed on the second side of the common substrate and electrically coupled to the semiconductor die, for example to the die contact via the second electrical contact. Thus, an application circuit using the semiconductor package according to various embodiments can be simplified.

FIG. 5 shows a schematic perspective view of a semiconductor package 100 according to various embodiments of various embodiments. The semiconductor package 100 may include a common substrate 120 including a first side 121. The common substrate 120 may include, on the first side 121, a first electrical contact 125 and a second electrical contact 124. The semiconductor package 100 may include a semiconductor die 110, which semiconductor die 110 may be arranged on the first side 121 of the common substrate 120. The semiconductor die 110 may include a die contact (not shown) which is connected to the second electrical contact of the common substrate (not shown). The semiconductor package may include a mold structure 150, wherein the semiconductor die 110 is encapsulated by the mold structure 150. The semiconductor package 100 may also include a three-dimensional antenna 140 provided in the mold structure. The three-dimensional antenna 140 is electrically coupled to the first electrical contact 125. As explained above, in some embodiments, instead of a common substrate a first substrate and a second substrate may be provided, the first substrate may thus include, on the first side, a first electrical contact 125, the second substrate may thus include, on the first side, a second electrical contact 124. Accordingly, the semiconductor die 110 may be arranged on the first side 121 of a second substrate.

In various embodiments, and as illustrated in the FIG. 5 by way of example, the semiconductor package 100 may include an additional three-dimensional antenna 160. The common substrate 120 may include an additional electrical contact 126 electrically coupled to the additional three-dimensional antenna 160.

In various embodiments, the three-dimensional antenna 140 may include a hollow inner side 143. In various embodiments, the three-dimensional antenna 160 may include a hollow inner side 163.

In various embodiments, the method according to the invention further comprises providing a dielectric material onto the three-dimensional antenna (and/or additional three-dimensional antenna) thus forming a dielectric-lens antenna (ae). The dielectric material may be added to the inner side 143 (163). The inner side 143 (163) may be filled with the dielectric material, for example, completely filled to its border. The dielectric material may also protrude out of the antenna.

In some embodiments, the dielectric material may be pre-formed with a solid shape and placed in or on the antenna, e.g. by pick and place. Alternatively, in some embodiments, the dielectric material may be dispensed in form of a liquid and cured to form a solid dielectric lens.

In various embodiments, the three-dimensional antenna 140 and/or additional three-dimensional antenna 160, can be of any suitable shape. A conical horn shape with circular cross-section is used in the figures as example.

In various embodiments, the antenna 140 may include a shape which cross-section increases from the end 142 that is proximal to the common (or first) substrate 120 to the end 141 that is distal to the first substrate 120. The cross-section is taken at a plane perpendicular to the axis.

In various embodiments, the antenna 160 may include a shape which cross-section increases from the end 162 that is proximal to the common substrate 120 to the end 161 that is distal to the common substrate 120. The cross-section is taken at a plane perpendicular to the axis.

In various embodiments, the three-dimensional antenna 140 may include a conical shape, as example it may have a conical shape, further it may be a conical horn antenna. In various embodiments, the additional three-dimensional antenna 160 may include a conical shape, as example it may have a conical shape, further it may be a conical horn antenna. Conical horn antennae may have the effect of providing a slim (focused) radar radiation pattern and providing a directivity, due to the directional radiation pattern with high antenna gain, which can range e.g. up to 25 dB. Conical horn antennae have shown to provide long and short range radar sensing. The conical cross-section may be of any suitable geometry, e.g. elliptic, e.g. circular. The cross-section is taken at a plane perpendicular to the axis of the antenna.

In various embodiments, the inner side 143 of the three-dimensional antenna 140 may be empty, e.g. only filled with air.

In various embodiments, the inner side 163 of the three-dimensional antenna 160 may be empty, e.g. only filled with air.

In various embodiments, the inner side 143 of the three-dimensional antenna 140 may be at least partially filled, e.g. with a dielectric.

In various embodiments, the inner side 163 of the three-dimensional antenna 160 may be at least partially filled, e.g. with a dielectric.

A conical horn antenna, with or without dielectric filling may be used for middle and/or short range sensing, e.g. for lane departure warning in automotive vehicles.

In various embodiments, the three-dimensional antenna 140 may include a conical horn antenna and the common substrate includes first substrate contacts on the second side 122 of the common substrate. Thus, a leadless package can be provided with a high level of integration, lowering the space required for the use in an application board.

In various embodiments, the providing a three-dimensional antenna includes forming a continuous conductive surface on at least part of the surface of the opening of the mold structure.

In various embodiments, the three-dimensional antenna 140 may be structured. This may have the effect that material, such as metal, can be saved, while the efficiency of the antenna is not negatively affected, or may even be improved. Examples of structures are patterns, such as in the form of a trace of metal.

In various embodiments, the step of providing a three-dimensional antenna includes forming a trace in form of a helix on at least part of the surface of the opening of the mold structure.

The term “trace” used herein may mean an elongated, e.g. continuous, trace of conductive material, e.g. of a metal alloy or a metal.

FIG. 6 shows a schematic perspective view of a semiconductor package in accordance with various embodiments, wherein the three-dimensional antenna(e) may include a metal trace. In various embodiments, it may be provided that the antenna(e) may include a helix. In various embodiments, the helix may include a variable radius which increases with distance from the first substrate, for example a conical helix as illustrated in FIG. 6.

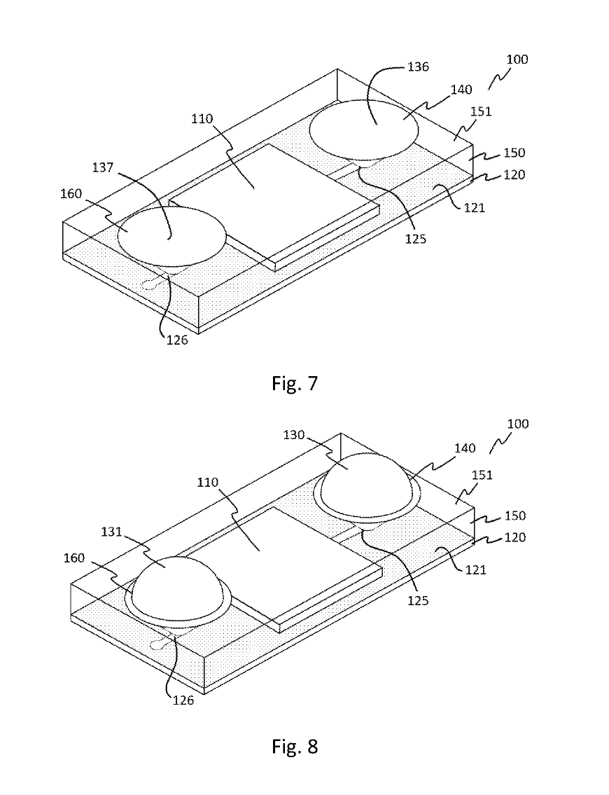

FIG. 7 shows a schematic perspective view of a semiconductor package 100 according to various embodiments. FIG. 7 illustrates, by way of example, a semiconductor package 100. In various embodiments, the semiconductor package 100, may include a three-dimensional antenna 140. In various embodiments, the semiconductor package 100, may include an additional three-dimensional antenna 160. The three-dimensional antenna 140 may include a dielectric material, for example, to further shape the radiation profile. The three-dimensional antenna 140 may be filled with the dielectric material 136. In one example, the upper surface 151 of the mold structure 150 and the surface of the three-dimensional antenna, which is distal from the first substrate 120, are part of the same surface, for example coplanar. Filling with a dielectric changes the radiation pattern, thus providing a flexibility in adjusting the radiation pattern during forming the semiconductor package 100. When the package 100 includes an additional three-dimensional antenna 160, the additional three-dimensional antenna 160 may also include a dielectric material, for example, to further shape the radiation profile. The upper surface 151 of the mold structure 150 and the surface of the additional three-dimensional antenna, which is distal from the first substrate 120, may be part of the same surface, for example coplanar.

In various embodiments, the providing the dielectric-lens antenna may further include forming at least one metal trace on the surface of the lens. The forming the at least one metal trace may include laser metallization or laser structuring followed by electroless plating.

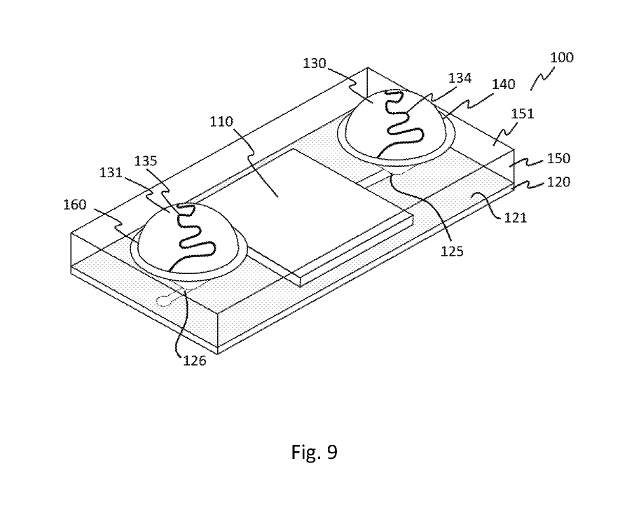

FIG. 8 shows a schematic perspective view of a semiconductor package 100 according to various embodiments. FIG. 8 illustrates, by way of example, a semiconductor package 100. In various embodiments, the semiconductor package 100, may include a three-dimensional antenna 140. The three-dimensional antenna 140 may include a dielectric material, for example, to further shape the radiation profile. The three-dimensional antenna 140 may include a dielectric lens 130. The dielectric lens 130 may have a shape as suitable for the application. In the example of FIG. 8, the dielectric lens 130 is hemispherical shaped. It was found that a semiconductor package 100 including a three-dimensional antenna 140 including a dielectric lens offers high directivity for very long range of radar radiation pattern, and can therefore be used in long range applications. For example, for emergency braking, pedestrian detection, collision avoidance, and especially for adaptive cruise control. When the package 100 includes an additional three-dimensional antenna 160, the additional three-dimensional antenna 160 may also include a dielectric material, for example, to further shape the radiation profile. The additional three-dimensional antenna 160 may include a dielectric lens 131. The dielectric lens 131 may have a shape as suitable for the application. In the example of FIG. 8, the dielectric lens 131 is hemispherical shaped.

FIG. 9 shows a schematic perspective view of a semiconductor package 100 according to various embodiments. The three-dimensional antenna 140 may include a dielectric material, which may be a lens 130, which material or lens may include a metal structure 134, or it may be fully plated. In the same manner, if an additional three-dimensional antenna 160 is provided, it may include a dielectric material, which may be a lens 131, which material or lens may include a metal structure 135, or it may be fully plated. The metal structure or the fully plated dielectric surface may be used to shape the radiation pattern.

In summary, various embodiments may provide several effects as explained above, including a more compact form of the semiconductor package, and flexibility of choice of the radiation pattern for different field of application.

What is claimed is:

1. A method of forming a semiconductor package, the method comprising:
providing a semiconductor die and a first substrate, wherein the semiconductor die comprises a die contact, wherein the first substrate comprises a first side, and wherein the first side comprises a first electrical contact;
forming a mold structure to encapsulate the semiconductor die and the first substrate; and
providing a three-dimensional antenna in the mold structure to electrically couple to the first electrical contact.

2. The method of claim 1, wherein the mold structure comprises an opening exposing at least a portion of the first electrical contact.

3. The method of claim 2, wherein the opening is at least partially formed during the forming of the mold structure.

4. The method of claim 2, wherein the opening is at least partially formed after the forming of the mold structure.

5. The method of claim 2, wherein the three-dimensional antenna is provided after forming the mold structure, and wherein the three-dimensional antenna is formed in the opening.

6. The method of claim 5, wherein providing the three-dimensional antenna comprises forming a trace in a form of a helix or a continuous conductive surface on at least part of a surface of the opening of the mold structure.

7. The method of claim 5, wherein the three-dimensional antenna is a pre-formed three-dimensional antenna.

8. The method of claim 1, wherein the three-dimensional antenna is provided before forming the mold structure, and wherein the three-dimensional antenna and the first substrate are arranged over one another before forming the mold structure.

9. The method of claim 1, further comprising:
providing a dielectric material onto the antenna to form a dielectric-lens antenna.

10. The method of claim 9, wherein providing the dielectric-lens antenna comprises forming at least one metal trace on the surface of the lens.

11. The method of claim 10, wherein forming the at least one metal trace comprises laser metallization or laser structuring followed by electroless plating.

12. The method of claim 1, wherein the antenna has a shape with a cross-section which increases from an end that is proximal to the first substrate to an end that is distal to the first substrate.

13. The method of claim 1, wherein the three-dimensional antenna comprises a continuous surface.

14. The method of claim 1, wherein the semiconductor die is provided on a second substrate, wherein the second substrate comprises a first side and a second side, wherein the first side comprises a second electrical contact, and wherein the second electrical contact is electrically coupled to the die contact.

15. The method of claim 14, wherein the first substrate and the second substrate are parts of a common substrate.

16. The method of claim 1, wherein the three-dimensional antenna is selected from the group consisting of: a conical horn antenna; a dielectric lens antenna; a dielectric lens antenna comprising metal traces on the lens; and/or a helix antenna.

17. A semiconductor package, comprising:
a first substrate comprising a first side and a second side, wherein the first side includes a first electrical contact;
a semiconductor die comprising a die contact;
a mold structure encapsulating the semiconductor die and the first substrate; and
a three-dimensional antenna disposed in the mold structure and electrically coupled to the first electrical contact.

18. A semiconductor package of claim 17, wherein the three-dimensional antenna is disposed into at least part of an opening of the mold structure.

19. A semiconductor package of claim 17, wherein the antenna has a shape with a cross-section which increases from an end that is proximal to the first substrate to an end that is distal to the first substrate.

20. A semiconductor package of claim 17, wherein the three-dimensional antenna is selected from the group consisting of: a conical horn antenna; a dielectric lens antenna; a dielectric lens antenna comprising metal traces on the lens; and/or a helix antenna.
